(19) United States
(12) Patent Application Publication
(10) Pub. No.: US 2010/0126576 A1
(43) Pub. Date: May 27, 2010

(54) SILICON MATERIAL SURFACE ETCHING FOR LARGE POLYSILICON THIN FILM DEPOSITION AND STRACTURE

(75) Inventor: JIAN ZHONG YUAN, Simi City, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Jian Zhong Yuan, Simi Valley, CA (US)

(21) Appl. No.: 12/431,734

(22) Filed: Apr. 28, 2009

Related U.S. Application Data
(60) Provisional application No. 61/048,535, filed on Apr. 28, 2008.

(51) Int. Cl. H01L 31/00; H01L 31/0368

(52) U.S. Cl. 136/256; 438/97; 257/E31.043

(57) ABSTRACT

A method for forming a photovoltaic cell. The method includes providing a first silicon material characterized by a resistivity less than about 0.5 ohm cm⁻¹ and a first conductive type impurity characteristic. The first silicon material forms a first conductor layer for a photovoltaic cell. The method deposits a polysilicon film material overlying the surface region. In a specific embodiment, the polysilicon material has the first conductive type impurity characteristics and a resistivity greater than about 0.5 ohm cm⁻¹. In a specific embodiment, the first polysilicon film material is characterized by a grain size greater than about 0.1 mm. The method forms a second conductive type impurity region having a second conductive type impurity characteristics opposite to the first conductive type impurity characteristics in a vicinity of a first surface region of the polysilicon film material. A second conductor layer overlies the second conductive type impurity region to form a photovoltaic cell.

### CROSS-REFERENCES TO RELATED APPLICATIONS

This application claims priority to U.S. Provisional Patent Application No. 61/048,535 filed Apr. 28, 2008, in the name of Jian Zhong Yuan, and hereby incorporate for reference for all purpose.

The present invention is directed to photovoltaic material. More particularly, the present invention provides a conductor layer for a photovoltaic cell. Merely by way of example, the present method and structure have been applied using a silicon material, but it would be recognized that the invention may be implemented using other materials.

Increasing population growth and industrial expansion have lead to a large consumption of energy. Energy often comes from fossil fuels, including coal and oil, hydroelectric plants, nuclear sources, and others. Almost every element of our daily lives uses fossil fuel, which is becoming increasingly scarce. Accordingly, other alternative sources of energy have been developed to supplement or to replace energy derived from fossil fuels.

Solar energy possesses many desirable characteristics. Solar energy is renewable, clean, abundant, and often widespread. Certain technologies developed often capture solar energy, store it, and convert it into other useful forms of energy, for example, electrical and/or thermal energy.

Solar devices have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Accordingly, solar panels have great benefit to human users. They can diversify our energy requirements and reduce the world's dependence on oil and other potentially detrimental sources of energy.

Although solar devices have been used successful for certain applications, there are still certain limitations. For example, solar cells are often composed of silicon bearing wafer materials, which are often costly and difficult to manufacture efficiently on a large scale. Accordingly, there is a limited sources of photovoltaic silicon bearing material. These and other limitations are described throughout the present specification, and may be described in more detail below.

From the above, it is seen that techniques for providing silicon bearing material for photovoltaic application is highly desirable.

### BRIEF SUMMARY OF THE INVENTION

Embodiments according to the present invention are directed to photovoltaic material. More particularly, embodiments according to the present invention provide a conductor layer for a photovoltaic cell. Merely by way of example, the present method and structure have been applied using a silicon material, but it would be recognized that the invention may be implemented using other materials.

In a specific embodiment, a method for forming a photovoltaic cell is provided. The method includes providing a first silicon material. The first silicon material includes a surface region. In a specific embodiment, the first silicon material is characterized by a first conductive type impurity characteristic and a resistivity less than about 0.5 ohm cm⁻¹. In a specific embodiment, the first silicon material provides a first conductor layer for the photovoltaic cell. The method includes forming a polysilicon film material using a deposition process overlying the surface region of the first silicon material. The polysilicon film material is characterized by the first conductive type impurity characteristics and a resistivity greater than about 0.5 ohm cm⁻¹. In a specific embodiment, the first polysilicon film material is characterized by a grain size greater than about 0.1 mm. The method forms a second conductive type impurity region in a vicinity of a first surface region of the polysilicon film material. A second conductor layer is formed overlying the second impurity region.

In an alternative embodiment, a photovoltaic cell structure is provided. The photovoltaic cell structure includes a first silicon material having a surface region. In a specific embodiment, the first silicon material provides for a first conductor layer for a photovoltaic cell. The first silicon material is characterized by a resistivity less than about 0.5 ohm cm⁻¹ and a first conductive type impurity characteristic in a specific embodiment. The photovoltaic cell structure includes a polysilicon film material overlying the surface region of the first silicon material. The polysilicon film material has the first conductive type impurity characteristics and a resistivity greater than about 0.5 ohm cm⁻¹ and is characterized by a grain size greater than about 0.1 mm in a preferred embodiment. A second conductive type impurity region is provided in a vicinity of a first surface region of the polysilicon film material. The second conductive type impurity region has a second conductive type impurity characteristics opposite to the first conductive type impurity characteristics. The photovoltaic cell structure includes a second conductor structure overlying the second conductive type impurity region.

Many benefits are achieved by way of present invention over conventional techniques. For example, the present technique provides an easy to use process that relies upon convention technology. In some embodiments, the present method provides a silicon material having a suitable conductivity to form a conductor layer for a photovoltaic cell. The silicon material can be a low cost alternative to the conventional conductor material used in photovoltaic device application. Additionally, the method provides a process that is compatible with conventional process technology without substantial modifications to conventional equipment and processes. Depending upon the embodiment, one or more these benefits may be achieved. These and other benefits will be described in more detail throughout the present specification and more particularly below.

### BRIEF DESCRIPTION OF THE DRAWINGS

FIG. 1 is a simplified flow diagram illustrating a method for forming a photovoltaic cell according to an embodiment of the present invention.

FIG. 2-5 are simplified diagrams illustrating a method for fabricating a photovoltaic cell according to an embodiment of the present invention.

### DETAILED DESCRIPTION OF THE INVENTION

According to embodiments of the present invention, techniques related to photovoltaic materials are provided. More particularly, embodiments according to the present invention provides a method to form a conductor layer for a photovoltaic cell. Merely by way of example, the present method has been applied using a silicon material, but it would be recognized that embodiments according to present invention can use other materials. Further details of the embodiments of the present invention can be found throughout the present specification and more particularly below.

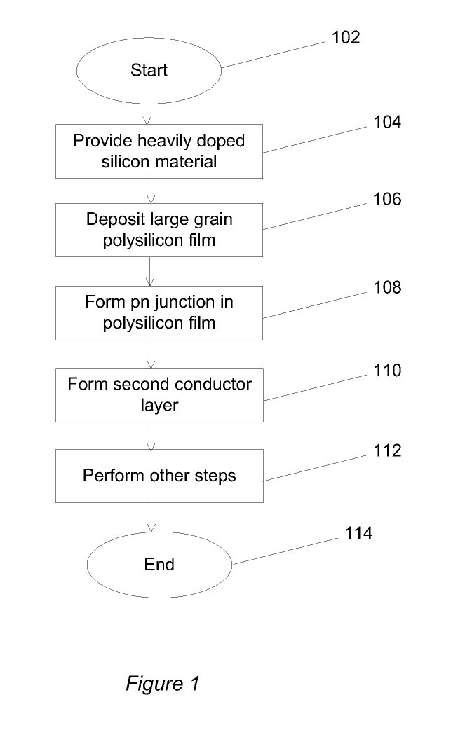

FIG. 1 is a simplified flow diagram illustrating a method of forming a photovoltaic cell according to an embodiment of the present invention. As shown, the method begins with a start step (Step 102). A heavily doped silicon material characterized by a first conductive type is provided (Step 104). The heavily doped silicon material provides a first conductor layer for the photovoltaic cell in a specific embodiment. The method deposits a large grain polysilicon film overlying a surface region of the heavily doped silicon material (Step 106). The large grain polysilicon film is characterized by the first conductive type and a grain size greater than about 0.1 mm. The method also includes forming a pn junction within the large grain polysilicon film in a vicinity of a surface region of the large grain polysilicon film (Step 108). The method forms a second conductor layer overlying the surface region of the large grain polysilicon film (Step 110). The method performs other steps (Step 112) as desired. The method includes an end step (Step 114).

The above sequence of steps provides a method of forming a photovoltaic cell according to an embodiment of the present invention. As shown, the method uses a combination of steps including a way of providing a conductor layer for a photovoltaic cell in a specific embodiment. Other variations and alterations can also be provided where one of more steps are added, one or more steps are removed, or one or more steps are provided in a different sequence without departing form the scope of claims therein. One skilled in the art would recognize many other variations, modifications, and alternatives.

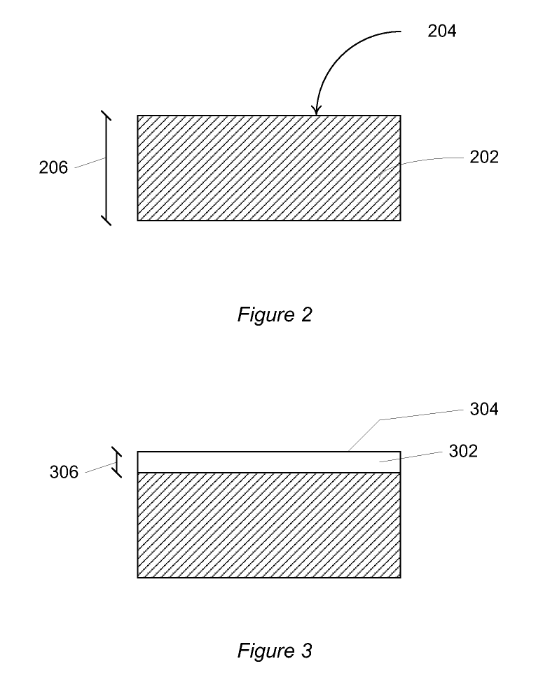

FIG. 2-5 are simplified diagrams illustrating a method of forming a photovoltaic according to an embodiment of the present invention. These diagrams are merely examples and should not unduly limit the claims herein. One skilled in the art would recognize other variations, modifications, and alternatives. As shown in FIG. 2, a silicon wafer material 202 is provided. The silicon wafer material can be provided as a wafer having a thickness 206 and includes a surface region 204. In a specific embodiment, the silicon wafer material is doped with a first conductive type impurity species to provide for a resistivity less than about 0.5 ohm cm⁻¹. The first conductive type impurity species can be a P⁺⁺ type impurity provided by, for example, a boron species. In an alternative embodiment, the P⁺⁺ type impurity may be provided using a gallium species or other suitable P type impurity species. Alternatively, the first conductive type impurity species can be an N⁺⁺ type impurity species provided by, for example, a phosphorus species, an arsenic species, or an antimony species, but can be others, depending on the application. In a specific embodiment, the silicon wafer material is characterized by a grain size. Preferably, the first wafer silicon material is characterized by a large grain size, for example, greater than about 0.1 mm.

The first conductive type impurity species can be incorporated into a silicon material by, for example, adding the first conductive type impurity species to a molten silicon and subjecting the molten silicon including the first type impurity species to a controlled cooling process. The silicon material is usually takes on a shape of a cooling vessel and can be cut and sliced into desired thickness and shape after cooling. The controlled cooling process can be a directional cooling process in a specific embodiment. Further details of the directional cooling process can be found in U.S. Patent Application (Attorney Docket No.: 027133-000500US), in the name of Jianzhong Yuan, and hereby incorporated by reference herein. Other processes may also be used, depending on the embodiment. For example, a diffusion process may be used to doped the silicon wafer material. Other processes may include implantation process using high energy ions derived from the impurity species. Of course there can be other variations, modifications, and alternatives.

In a specific embodiment, a polysilicon film material 302 is deposited overlying a surface region of the silicon wafer material as shown in FIG. 3. As shown, the polysilicon material includes a surface region 304 and a thickness 306. The polysilicon material is preferably a large grain polysilicon silicon material, for example, having a grain size grater than 0.1 mm. The polysilicon film material may be deposited using a variety of suitable techniques. These techniques include an epitaxial growth process, a liquid epitaxial growth process, a chemical vapor deposition process, or a physical vapor deposition process depending on the embodiment. In a specific embodiment, the polysilicon film material is usually doped to have a like impurity characteristics as the silicon wafer material, that is, the first impurity type. For example, the polysilicon film material is doped with a P type impurity for a silicon wafer material that has a P⁺⁺ type impurity characteristics. In a specific embodiment, the polysilicon film material is characterized by a resistivity less that about 0.5 ohm cm⁻¹ suitable for forming a junction region for a photovoltaic cell. Of course there can be other variations, modifications, and alternatives.

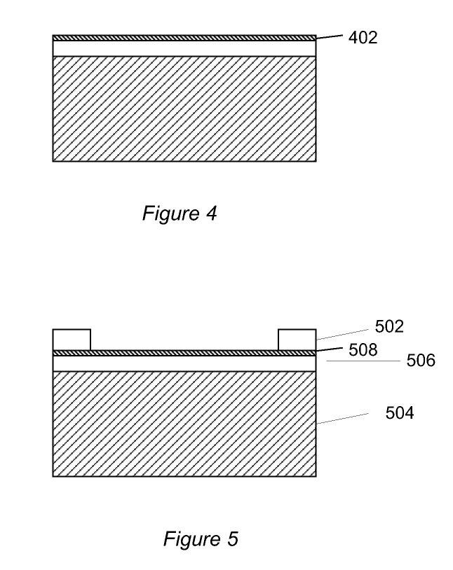

In a specific embodiment, a second impurity region 402 is provided in a vicinity of the surface region of the polysilicon film material as illustrated in FIG. 4. The second impurity region is characterized by an opposite conductive type impurity in the polysilicon film material. For example, for a P-type polysilicon film material, the second impurity region has an N type impurity characteristic. The first impurity and the second impurity region cause a p-n junction to form in the vicinity of the surface region of the polysilicon film material.

The method performs other steps to form a photovoltaic cell structure 500 as shown in the simplified diagram in FIG. 5. These other steps include, for example, forming a second conductor structure 502 overlying the second impurity region. The second conductor structure can be a metal material in certain embodiments. The method may include providing optical coating and the like to enhance the efficiency of the photovoltaic cell.

As shown in FIG. 5, the photovoltaic cell structure includes a first silicon layer 504 having a surface region. In a specific embodiment, the first silicon layer is characterized by a resistivity less than about 0.5 ohm cm⁻¹ and a first conductive type impurity characteristic to provides a first conductor layer for the photovoltaic cell structure. The photovoltaic cell structure includes a polysilicon film material 506 overlying the surface region of the first silicon layer, the polysilicon material has the first conductive type impurity characteristics and a resistivity greater than about 0.5 ohm cm⁻¹. In a specific embodiment, the first polysilicon film material is characterized by a grain size greater than about 0.1 mm. As shown, a second conductive type impurity region 508 is provided in a vicinity of a first surface region of the polysilicon film material. The second conductive type impurity region has a second conductive type impurity characteristics opposite to the first conductive type impurity characteristics. The second conductor layer overlies the second conductive type impurity region. Of course there can be other variations, modifications, and alternatives.

It is also understood that the examples and embodiments described herein are for illustrative purposes only and that various modifications or alternatives in light thereof will be suggested to persons skilled in the art and are to be included within the spirit and purview of this application and scope of the appended claims.

What is claimed is:

1. A method for forming a photovoltaic cell, comprising:
providing a first silicon material having a surface region; the first silicon material providing a first conductor layer for a photovoltaic cell, the first silicon material being characterized by a resistivity less than about 0.5 ohm cm⁻¹ and a first conductive type impurity characteristic;
forming a polysilicon film material using a deposition process overlying the surface region, the polysilicon material having the first conductive type impurity characteristics and a resistivity greater than about 0.5 ohm cm⁻¹, the first polysilicon film material being characterized by a grain size greater than about 0.1 mm;
forming a second conductive type impurity region in a vicinity of a first surface region of the polysilicon film material, the second conductive type impurity region having a second conductive type impurity characteristics opposite to the first conductive type impurity characteristics; and
forming a second conductor layer overlying the second conductive type impurity region.

2. The method of claim 1 wherein the first silicon material is further characterized by a first purity level greater than about 1N (0.9 silicon purity).

3. The method of claim 1 wherein the first conductive type impurity characteristics in the first silicon material has a P⁺⁺ type impurity characteristics, the P⁺⁺ type impurity being provided by a boron species or a gallium species at a concentration greater than about 3×10¹⁶ atoms cm⁻³.

4. The method of claim 3 wherein the second conductive type impurity region is has an N type impurity characteristic.

5. The method of claim 1 wherein the first conductive type impurity characteristics in the first silicon material is a N⁺⁺ type impurity characteristics, the N⁺⁺ type impurity characteristics being provided by a phosphorus species, or an arsenic species, or an antimony species at a concentration greater than about 1×10¹⁶ atoms cm⁻³.

6. The method of claim 5 wherein the second conductive type impurity region is has a P type impurity characteristic.

7. The method of claim 1 wherein the first silicon material has a thickness greater than about 150 microns.

8. The method of claim 1 wherein the polysilicon material is deposited using an epitaxial growth process, a liquid epitaxial growth process, a chemical vapor deposition process, or a physical vapor deposition process.

9. The method of claim 1 wherein the polysilicon material is characterized by a thickness ranging from about 0.1 micron to about 200 microns.

10. The method of claim 1 wherein the first impurity and the second impurity type region in the polysilicon film material cause formation of a pn junction for the photovoltaic cell.

11. A photovoltaic cell structure, comprises:
a first silicon material having a surface region; the first silicon material providing a first conductor layer for a photovoltaic cell, the first silicon material being characterized by a resistivity less than about 0.5 ohm cm⁻¹ and a first conductive type impurity characteristic;
a polysilicon film material overlying the surface region, the polysilicon material having the first conductive type impurity characteristics and a resistivity greater than about 0.5 ohm cm⁻¹, the first polysilicon film material being characterized by a grain size greater than about 0.1 mm;
a second conductive type impurity region provided in a vicinity of a first surface region of the polysilicon film material, the second conductive type impurity region having a second conductive type impurity characteristics opposite to the first conductive type impurity characteristics; and
a second conductor layer overlying the second conductive type impurity region.

12. The photovoltaic cell structure of claim 11 wherein the first conductive type impurity characteristics in the first silicon material has a P⁺⁺ type impurity characteristics, the P⁺⁺ type impurity being provided by a boron species or a gallium species at a concentration greater than about 3×10¹⁶ atoms cm⁻³.

13. The photovoltaic cell structure of claim 12 wherein the second conductive type impurity region is has an N type impurity characteristic.

14. The photovoltaic cell structure of claim 11 wherein the first conductive type impurity characteristics in the first silicon material is a N⁺⁺ type impurity characteristics, the N⁺⁺ type impurity characteristics being provided by a phosphorus species, or an arsenic species, or an antimony species at a concentration ranging from about 1×10¹⁶ atoms cm⁻³.

15. The photovoltaic cell structure of claim 14 wherein the second conductive type impurity region has a P type impurity characteristic.

16. The photovoltaic cell structure of claim 11 wherein the first silicon material has a thickness greater than about 150 microns.

17. The photovoltaic cell structure of claim 11 wherein the polysilicon material is deposited using an epitaxial growth process, a liquid epitaxial growth process, a chemical vapor deposition process, or a physical vapor deposition process.

18. The photovoltaic cell structure of claim 11 wherein the polysilicon material is characterized by a thickness ranging from about 0.1 micron to about 200 microns.

19. The photovoltaic cell structure of claim 11 wherein the first impurity and the second impurity type region in the polysilicon film material cause formation of a pn junction
